(19) United States
(12) Patent Application Publication
(10) Pub. No.: US 2005/0093136 A1
(43) Pub. Date: May 5, 2005

(54) Thermal dissipating element of a chip

(76) Inventors: Wei-Chi Liu, Ping-Tung City (TW); Wei-Feng Lin, Hsin-Chu City (TW); Chung-Ju Wu, Kaohsiung City (TW)

Correspondence Address: NATH & ASSOCIATES, 1030 15th STREET, NW, 6TH FLOOR, WASHINGTON, DC, 20005, US

(21) Appl. No.: 10/698,476

(22) Filed: Nov. 3, 2003

(51) Int. Cl. H01L 23/10

(52) U.S. Cl. 257/707

(57) ABSTRACT

The present invention relates to a thermal dissipating element of a chip to dissipate heat producing by operating the chip. The thermal dissipating element includes a cover and a lump. The cover includes a top plate and a side plate, wherein the top plate curves and extendedly connects to the side plate. The lump is fastened between the chip and the top plate of the cover.

### BACKGROUND OF THE INVENTION

1. Field of the Invention

The present invention relates to a thermal dissipating element of a chip, and more particularly, to a thermal dissipating element having a lump.

2. Description of the Prior Art

A chip packaging element always includes a thermal dissipating element to dissipate the heat produced by operating a chip. However, for protecting the wire bonds connecting a substrate and the chip thereon from being short circuit, the space between the thermal dissipating element and the substrate is full of an EMC, Epoxy Molding Compound. The heat produced by operating the chip is difficult to be conducted from the chip to the thermal dissipating element due to the low heat conductivity of the EMC. The reliability of the chip packaging element is reduced due to the mass heat that can not be conducted to the thermal dissipating element.

As shown in FIG. 1A, the prior chip packaging element includes a cover 11 and a chip 1 8. The cover 11 includes a top plate 13, a side plate 15 and a sole plate 17. The top plate 13 curves and extendedly connects to the side plate 15. The side plate 15 curves and extendedly connects to the sole plate 17. The sole plate 17 contacts with and fastens on a substrate 19. The chip 18 electrical connects with the substrate 19 by wire bonds that are not shown in FIG. 1A. An EMC 191 is formed on the substrate 19, the cover 11 and the chip 18 to protect the cover 11 from the external force and protect the wire bonds from being short circuit.

There is a void or an air trap 193 formed inside the EMC 18. The air trap 193 effects the quality of the chip packaging element.

The air trap 193 appears during the packaging process for packaging the chip packaging element. During compressing the melting EMC 191 into the cover 11, the air trap 193 may be produced because air in the room is also compressed into the cover carelessly. The air trap 193 may be produced because water vapor and volatile composition of the EMC 191 being compressed into the cover 11 evaporates to be the air trap 193 during a follow-up heating step of the packaging process. The air trap 193 may also appear due to a lead-lag flow of the melting EMC 191 when the melting EMC 191 is compressed into the cover 11.

As shown in FIG. 1B, mold flow R of the EMC 191 is formed during the compressing process for compressing the EMC 191 into the cover 11 through the holes 151. The shape of the mold flow R is uniform before the EMC 191 contacting with the chip 18. The shape of the mold flow R′ is non-uniform while the EMC 191 contacting with the chip 18. A portion of the mold flow R′ contacting with the chip 18 lags while the other portion of the mold flow R′ that does not contact with the chip 18 remaining at the same velocity. Until the melting EMC 191 filling the cover 11 and being compressed out of the holes, the leading portion of the mold flow R′ surrounds the space among the lagged portion and the leading portion of the mold flow R′ to form the air trap 193.

The air trap 193 of the EMC 191 effects the reliability and the quality of the chip packaging element. When the chip 18 is tested or operated, the heat produced by the chip 18 expands the air trap 193 to raise the pressure inside the EMC 191. The EMC 191 may be broken to appear the popcorn condition due to the high pressure inside the air trap 193. The chip packaging element and the electrical element including the chip packaging element may be broken because of the popcorn condition. Besides, if there is vapor in the air trap 193, the ion of vapor inside the air trap 193 may corrode the chip 18 to reduce the period of validity of the chip packaging element. The mechanical strength and the thermal dissipating efficiency of the EMC 191 reduces because of the air trap 193. It is necessary to prevent the air trap 193 during compressing the melting EMC 191 and during the whole packaging process. Compressing the melting EMC 191 slower is an effective method for preventing the air trap 193 inside the EMC 191. However, the preventing method for compressing the melting EMC 191 slower lasts more than about 4-6 seconds during the whole packaging process.

According to the above description, it is necessary to develop an element to prevent the air trap inside the EMC and dissipate the heat more effectively.

### SUMMARY OF THE INVENTION

According to the above description of the background of the invention, it is one objective of the present invention to provide a thermal dissipating element of a chip of a chip packaging element to increase the heat dissipating efficiency by a lump having high heat conductivity.

It is an another objective of the present invention to provide a thermal dissipating element of a chip of a chip packaging element to increase the heat dissipating efficiency and prevent the air trap for protecting the chip packaging element at the same time.

It is a further objective of the present invention to provide a thermal dissipating element of a chip of a chip packaging element to prevent the air trap for remaining the mechanical strength and the reliability of the chip packaging element. The present thermal dissipating element also increases the period of validity of the chip packaging element.

It is a further objective of the present invention to provide a thermal dissipating element of a chip of a chip packaging element to increase the heat dissipating efficiency, increase the efficiency for the whole packaging process and reduce the time for compressing the melting packing material.

It is a further objective of the present invention to provide a thermal dissipating element of a chip of a chip packaging element to reduce the amount and the cost of a packing material.

It is a further objective of the present invention to provide a thermal dissipating element of a chip of a chip packaging element to increase the efficiency for recycling the recycled material having high heat conductivity.

The present invention provides a thermal dissipating element including a cover and a lump. The cover includes a top plate and a side plate, wherein the top plate curves and extendedly connects to the side plate. The top plate has a top surface and a bottom surface. The lump includes a top face, a bottom face and a side. The lump is fastened inside the cover, wherein the top face is fastened on the bottom surface.

All these advantageous features as well as others that are obvious from the following detailed description of the preferred embodiments of the invention are obtained.

### BRIEF DESCRIPTION OF THE DRAWINGS

FIG. 1A is a sectional view of a chip packaging element in the prior art;

FIG. 1B is a schematic diagram of a compressing process in the prior art;

FIG. 2 is a sectional view of a thermal dissipating element of the first embodiment of the present art;

FIG. 3 is a sectional view of a chip packaging element of the first embodiment of the present art

FIG. 4 is a sectional view of a chip packaging element of the second embodiment of the present art;

FIG. 5 is a sectional view of a chip packaging element of the third embodiment of the present art ; and

FIG. 6 is a schematic diagram of a compressing process in the present invention.

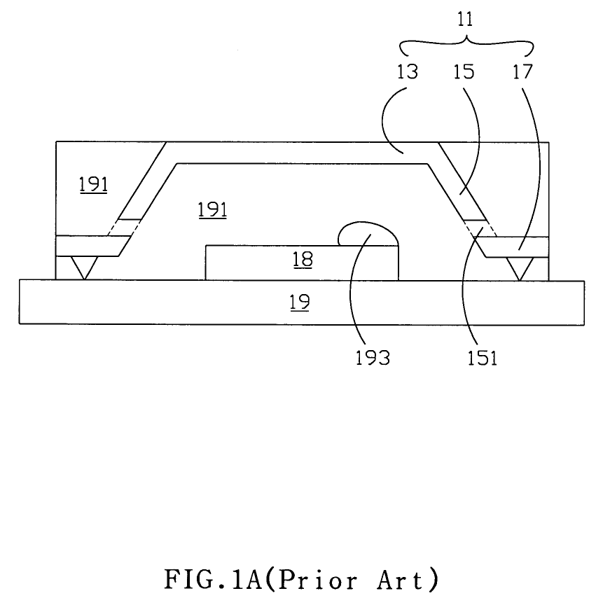

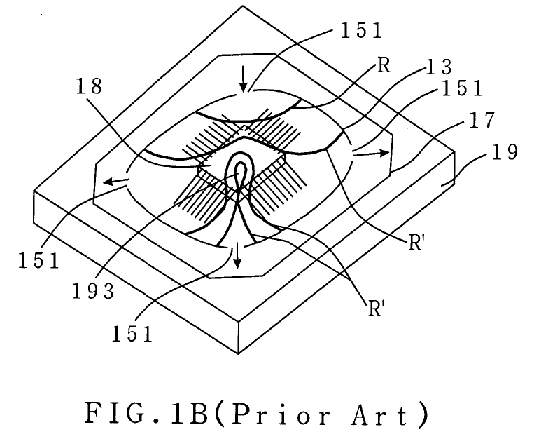

### DESCRIPTION OF THE PREFERRED EMBODIMENT

In the present disclosure, the words “a” or “an” are to be taken to include both the singular and the plural. Conversely, any reference to plural items shall, where appropriate, include the singular.

The preferred embodiments of the present invention provide a thermal dissipating element of a chip to improve the disadvantages of the prior art. Nonetheless, it should be recognized that the present invention can be practiced in a wide range of other embodiments besides those explicitly described, and the scope of the present invention is expressly not limited except as specified in the accompanying claims.

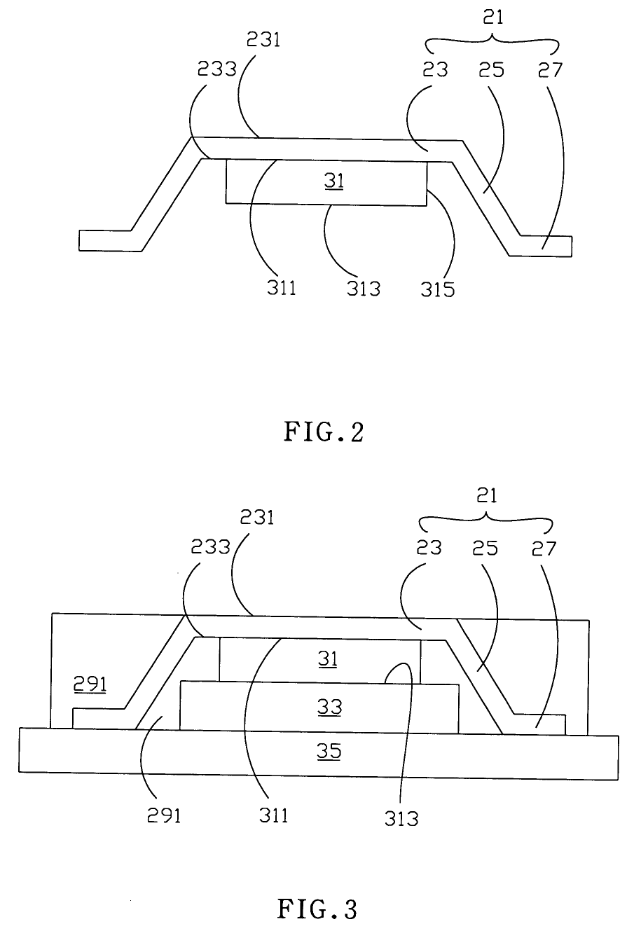

As shown in FIG. 2, a thermal dissipating element of a cover 21 and a lump 31. The cover 21 includes a top plat 23, a side plate 25 and a sole plate 27. The top plate 23 curves and extendedly connects to the side plate 25 and has a top surface 231 and a bottom surface 233 being the opposite of the top surface 231. The side plate 25 curves and extendedly connects to the sole plate 27. The lump 31 includes a top face 311, a bottom face 313 and a side face 315. The lump 31 is fastened inside the cover 21. The top face 311 of the lump 31 contacts with a portion of the bottom surface 233 of the cover 21.

As shown in FIG. 3, the thermal dissipating element of the present invention is fastened on a chip 33, wherein the bottom face 313 of the lump 31 contacts with a portion of the chip 33. The sole plate 27 is fastened on a substrate 35. The space on the chip 33 and the thermal dissipating element is filled with a packing material 291 to protect the wire bonds connecting the chip 31 and the substrate 35 from being short circuit and protect the cover 21 from hitting by unexpected force, i.e. the external force. The packing material 291 may be the EMC or any kind of material having the similarly protecting properties.

The lump 31 may be a silicon chip. The material of the lump 31 may also be metal, i.e. aluminum or copper, or something having high thermal conductivity. The heat producing by operating the chip 33 is conducts from the chip 33 to the cover 21 through the lump 31 having high thermal conductivity. Both the top surface 231 on the top plate 23 and any portion, which is not covered by anything, of the cover 21 dissipate the heat quickly. The lump 31 is fastened between the cover 21 and the chip 33 by an adhesive with high thermal conductivity. The lump 31 may be fastened on the chip 33 and the cover 21 by another method if the method could conduct the heat more quickly and fasten the elements on each other better.

Comparing the chip packaging element with the present thermal dissipating element and the prior chip packaging element, the thermal dissipating efficiency of the chip packaging element with the present thermal dissipating element is obviously better than that of the prior chip packaging element. The only method for conducting heat produced by operating the chip 18 from the chip 18 to the top plate 13 is conducted through the EMC 191 having low thermal conductivity. Even though the whole cover 11 and the top plate 13 having high thermal conductivity, the mass heat produced by the chip 18 is difficult to be conducted from the chip 18 to the top plate 13 through the EMC 191. The present thermal dissipating element including the lump 31 that has the high heat conductivity to conduct the heat produced by the chip 33 from the chip 33 to the cover 21 substantially increases the heat dissipating efficiency of the chip packaging element. Thus the heat dissipating efficiency of the prior chip packaging element is worse than that of the chip packaging element with the present thermal dissipating element. The reliability of the present chip packaging element is better than that of the prior chip packaging element because of the different between the lump 31 and the EMC 191. The heat produced by the chip 33 is dissipated well, so that the quality of operating the chip 33 remains well. Furthermore, the material of the lump 31 is chosen from any solid having high heat conductivity, the present chip packaging element could also recycle the recycled material, i.e. the inferiority silicon chip, having high heat conductivity. If a recycled material is chosen to be the lump 31, the complex recycling process for recycling the recycled material could be omitted and the recovery efficiency of the recycled material increases because of the present invention.

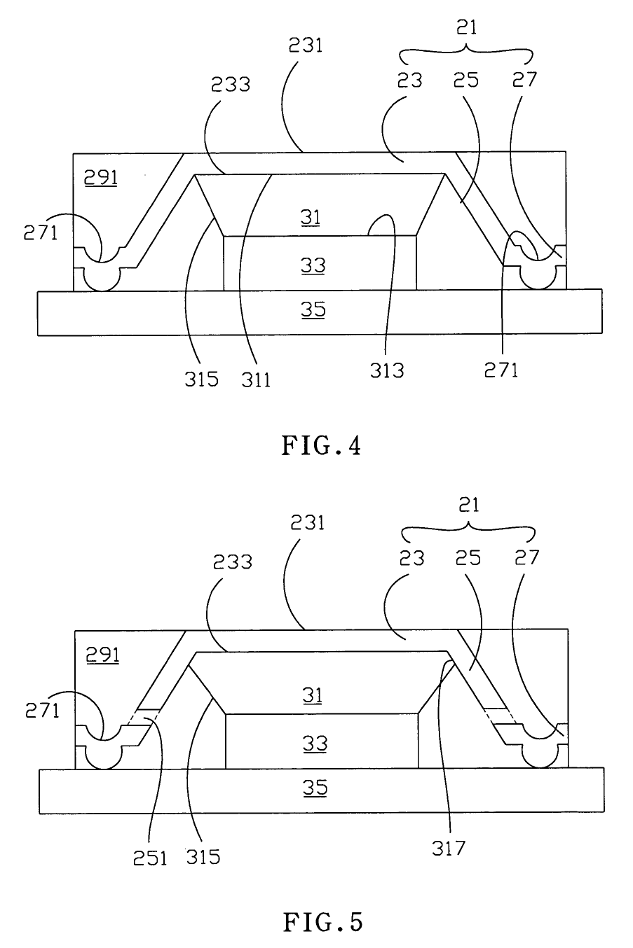

According to FIG. 4, the sole plate 27 of the second embodiment of the present invention includes a plurality of cavities 271. The bottom face 313 of the lump 31 is fastened on and contacts with the chip 33. The area of the bottom face 313 equals to the area of the chip 33 to conduct the heat produced by the chip 33 more quickly and more effectively. The area of the top face 311 of the lump 31 equals to the area of the bottom surface 233 of the cover 21. Thus the lump 31 is fastened on all of the bottom surface 233. The area between the lump 31 and the chip 33 of the second embodiment is larger than the area between the lump 31 and the chip 33 of the first embodiment of the present invention. The area between the lump 31 and the cover 21 of the second embodiment is also larger than the area between the lump 31 and the cover 21 of the first embodiment of the present invention. So that the heat produced by the chip 33 is dissipated more uniformly and effectively through the top plate 23 of the cover 21.

As shown in FIG. 5, the thermal dissipating element of the third embodiment of the present invention includes a plurality of holes between the side plate 25 and the sole plate 27. The packing material 291 filling the space between the cover 21 and the substrate 25 is compressed into the cover 21. The bottom face 313 of the lump 31 is fastened on and contacts with the chip 33. The area of the bottom face 313 of the lump 31 equals to the area of the chip 33 to conduct the heat produced by the chip 33 more effectively. The area of the top face 311 of the lump 31 also equals to the are a of the bottom surface 233 of the cover 21. Furthermore, a portion of the side 315, i.e. a part side 317, contacts with the side plate 25 to increase the conducted area between the lump 31 and the cover 21 for dissipating the heat more quickly and more uniform.

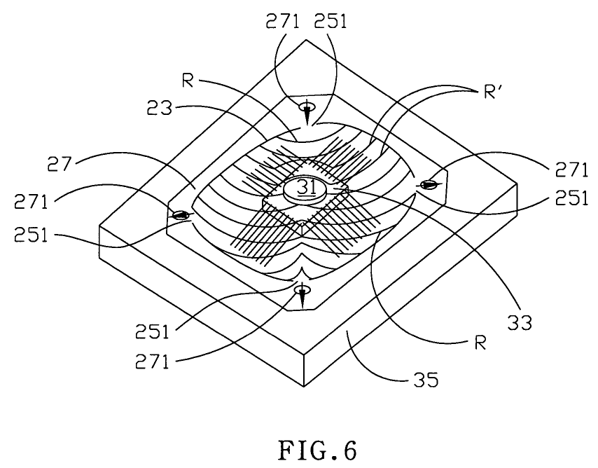

Moreover, mold flow R of the packing material 291 is formed during the compressing process for compressing the packing material 291 into the cover 21 through the holes 251, as shown in FIG. 6. The shape of the mold flow R is uniform before the packing material 291 contacting with the chip 33 and the lump 31. The shape of the mold flow R′ is non-uniform while the packing material 291 contacting with the chip 33 and the lump 31 because of the velocity of the packing material 291 on the chip 33 being slower than the velocity of the packing material 291 beside the chip 33. However, the velocity of the packing material 291 becomes more uniform after the packing material 291 with the slower velocity contacting with the lump 31. The packing material 291 is compressed into the cover 21 until the packing material 291 filling the space inside the cover 21 and the space on the substrate 35 for protecting the whole chip packaging element. Until the compressing process stop, the air trap does not appear because the lump 31 adjusts the difference between the faster velocity and the slower velocity of the packing material 291. By the way, the shape of the top face 311 and the bottom face 313 may be circular, as shown in FIG. 6, or quadrilateral as the chip 33, wherein the top face 311 and the bottom face 313 are not shown in FIG. 6 but shown in FIG. 3.

The lump 31 of the thermal dissipating element of the present invention reduces the packing material 291 filled between the cover 21 and the substrate 35 and the time for compressing the packing material 291 into the cover 21. For instance, a compressing process lasting about 12 seconds needs an extra time lasting about 4-6 seconds for preventing the air trap 193 inside the EMC 191 in the prior art. A compressing process for packaging the chip packaging element having the present thermal dissipating element needs less the amount and the cost of the packing material 291 and does not need the process for preventing the air trap 193 due to the lump 31. The whole compressing process becomes more quickly and more effectively due to the reduced amount of the packing material 291. The mechanical stress of the chip packaging element with the present thermal dissipating element having none of the air trap is much stronger than that of a chip packaging element including an air trap 193 to increase the reliability and the period of validity of the chip packaging element. Moreover, both the efficiency for recycling the recycled material having high heat conductivity and the efficiency for dissipating the heat produced by the chip increase due to the present invention.

The above description only demonstrates and illustrates the preferred embodiments of the present invention, but does not limit the scope of the present invention to what described detailed herein; and any equivalent variations and modifications of the present invention should be within the scope of the claims hereafter.

1. A thermal dissipating element of a chip, comprising:
a cover including a top plate and a side plate, said top plate curving and extendedly connecting to said side plate, wherein said top plate has a top surface and a bottom surface; and
a lump including a top face, a bottom face and a side, wherein said lump is fastened inside said cover, and said top face contacts with said bottom surface.

2. The thermal dissipating element according to claim 1, wherein said bottom face contacts with said chip.

3. The thermal dissipating element according to claim 1, wherein the shape of said bottom face is circular.

4. The thermal dissipating element according to claim 1, wherein the shape of said bottom face is quadrilateral.

5. The thermal dissipating element according to claim 1, wherein said top face is fastened on said bottom surface by an adhesive.

6. The thermal dissipating element according to claim 1, wherein the shape of said top face is circular.

7. The thermal dissipating element according to claim 1, wherein the shape of said top face is quadrilateral.

8. The thermal dissipating element according to claim 1, wherein said side contacts with said side plate.

9. The thermal dissipating element according to claim 1, wherein said lump is a silicon chip.

10. The thermal dissipating element according to claim 1, further comprising a sole plate to extendedly connect to said side plate.

11. The thermal dissipating element according to claim 10, said side plate and said sole plate including a plurality of holes, said holes being formed between said side plate and said sole plate.

12. The thermal dissipating element according to claim 10, wherein said sole plate includes a plurality of cavities.

13. The thermal dissipating element according to claim 1, wherein the material of said lump is metal.

14. The thermal dissipating element according to claim 13, wherein the material of said lump is aluminum.

15. The thermal dissipating element according to claim 13, wherein the material of said lump is copper.

16. A chip packaging element, comprising:
a substrate;
a chip fastened on said substrate; and
a thermal dissipating element of said chip, said thermal dissipating element including a top plate, a side plate, a sole plate and a lump, said top plate curving and extendedly connecting to the side plate, said side plate curving and extendedly connecting to the sole plate, said lump fastened on said top plate, wherein said sole plate is fastened on said substrate, said lump contacts with said chip, and said chip is fastened on said lump and said substrate.

17. The chip packaging element according to claim 16, wherein said lump is fastened on said top plate by an adhesive with high thermal conductivity.

18. The chip packaging element according to claim 16, wherein said lump contacts with a portion of said side plate.

19. The chip packaging element according to claim 16, said lump comprising a top surface and a bottom surface being opposite to each other, wherein said lump is fastened on a portion of said bottom surface.

20. The chip packaging element according to claim 16, said lump comprising a top surface and a bottom surface being opposite to each other, wherein said lump is fastened on all of said bottom surface.
